(19) United States
(12) Patent Application Publication
(10) Pub. No.: US 2013/0217164 A1
(43) Pub. Date: Aug. 22, 2013

(54) ORGANIC LAYER DEPOSITION APPARATUS, AND METHOD OF MANUFACTURING ORGANIC LIGHT EMITTING DISPLAY APPARATUS USING THE SAME

(71) Applicant: SAMSUNG DISPLAY CO., LTD., (US)

(72) Inventors: Hee-Cheul KANG, Yongin-City (KR); Jong-Heon KIM, Yongin-City (KR); Yun-Ho CHANG, Yongin-City (KR); Seok-Rak CHANG, Yongin-City (KR); Cheol-Lae ROH, Yongin-City (KR)

(73) Assignee: SAMSUNG DISPLAY CO., LTD., Yongin-City (KR)

(21) Appl. No.: 13/659,827

(22) Filed: Oct. 24, 2012

(30) Foreign Application Priority Data
Feb. 17, 2012 (KR) 10-2012-0016472

(51) Int. Cl. H01L 33/08

(52) U.S. Cl. 438/34; 118/500; 118/720; 438/46; 257/E33.013

(57) ABSTRACT

An organic layer deposition apparatus and a method of manufacturing an organic light emitting display apparatus by using the organic layer deposition apparatus. An organic layer deposition apparatus includes: a carrier including a chuck on which a substrate is mounted to form an organic layer; a scanning unit including a deposition unit for discharging a deposition raw material, and a patterning slit sheet having a plurality of patterning slits, the patterning slit sheet being smaller than the substrate in at least one of a first direction or a second direction perpendicular to the first direction; and a chamber accommodating the carrier and the scanning unit, the scanning unit being arranged to be spaced apart from the substrate and movable relative to the carrier.

### CROSS-REFERENCE TO RELATED APPLICATION

This application claims priority to and the benefit of Korean Patent Application No. 10-2012-0016472, filed on Feb. 17, 2012 in the Korean Intellectual Property Office, the entire content of which is incorporated herein by reference.

### BACKGROUND

1. Field

Aspects of embodiments of the present invention relate to an organic layer deposition apparatus and a method of manufacturing an organic light emitting display apparatus using the organic layer deposition apparatus.

2. Description of the Related Art

In general, organic light emitting display apparatuses have wide viewing angle, high contrast, and fast response time. Accordingly, organic light emitting display apparatuses may be applied to display devices for mobile devices such as digital cameras, video cameras, camcorders, portable information terminals, smartphones, ultra-slim laptop computers, tablet personal computers (PCs), and flexible display apparatuses, or electronic/electric products such as ultra-thin televisions.

In general, an organic light emitting display apparatus emits light when holes and electrons that are respectively injected in an anode and a cathode recombine in an organic light emission layer to emit light, in particular, when excitons that are formed by combining the holes and the electrons are changed to a base state from an excited state.

The organic light emitting display apparatus applied in a large-sized electronic device such as an ultra-thin television uses a large substrate. A thin film pattern layer such as an organic emission layer formed on the large substrate may be formed by depositing a raw material of the thin film pattern layer by using a mask having a pattern corresponding to the thin film pattern layer.

### SUMMARY

According to an aspect of embodiments of the present invention, an organic layer deposition apparatus is capable of performing a deposition process by moving a scanning unit with respect to a large-sized substrate to be applied in mass production and which simplifies a deposition process. According to another aspect of embodiments of the present invention, in a method of manufacturing an organic light emitting display apparatus, the organic layer deposition apparatus described above is used.

According to an embodiment of the present invention, an organic layer deposition apparatus includes: a carrier including a chuck on which a substrate is mounted to form an organic layer; a scanning unit including a deposition unit for discharging a deposition raw material, and a patterning slit sheet having a plurality of patterning slits, the patterning slit sheet being smaller than the substrate in at least one of a first direction or a second direction perpendicular to the first direction; and a chamber accommodating the carrier and the scanning unit, the scanning unit being arranged to be spaced apart from the substrate and movable relative to the carrier.

The deposition unit may include: a deposition source arranged at a side of the carrier to discharge the deposition raw material; a deposition source nozzle unit on the deposition source and comprising a plurality of nozzles; and a barrier plate assembly between the patterning slit sheet and the deposition source nozzle unit, and including a plurality of barrier plates partitioning a space between the patterning slit sheet and the deposition source nozzle unit into a plurality of sub-deposition spaces.

The patterning slit sheet may be spaced apart from the substrate.

The chuck may be installed on a surface of the substrate, which is opposite to a surface of the substrate facing the scanning unit, for supporting the substrate.

The substrate may include a plurality of substrates arranged in the chamber, and the scanning unit may be configured to reciprocate between the plurality of substrates.

The organic layer deposition apparatus may further include an align stage unit arranged at a lower portion of the patterning slit sheet and comprising at least a location controller for aligning the patterning slit sheet to be parallel with the substrate.

The scanning unit and the align stage unit may be integrally coupled to each other on a base frame for moving in connection with each other.

The chamber may include a plurality of chambers successively arranged, and the scanning unit may be configured to move in a direction in each of the chambers crossing a direction in which the carrier moves between adjacent chambers of the plurality of chambers in a step-in-line manner.

The chamber may include a plurality of chambers successively arranged, the substrate may include a plurality of substrates spaced apart from each other in a horizontal direction in each of the chambers, and the patterning slit sheet and the deposition unit may be successively arranged at a lower portion of the substrates in a vertical direction.

The patterning slit sheet and the deposition unit in each of the chambers may be configured to reciprocate between the plurality of the substrates horizontally in a direction, and the plurality of substrates may be movable between adjacent chambers of the plurality of chambers in a step-in-line manner in another direction crossing the direction.

The chamber may include a plurality of chambers successively arranged, the substrate may include a plurality of substrates spaced apart from each other in a vertical direction in each of the chambers, and the patterning slit sheet and the deposition unit may be successively arranged at a rear portion of the substrates in a horizontal direction.

The patterning slit sheet and the deposition unit in each of the chambers may be configured to reciprocate between the plurality of substrates in the vertical direction, and the plurality of substrates may be movable horizontally between adjacent chambers of the plurality of chambers.

The chamber may include a plurality of chambers arranged in a circulation form, the substrate may include a plurality of substrates spaced apart from each other in a vertical direction in each of the chambers, and the patterning slit sheet and the deposition unit may be successively arranged at a rear portion of the substrates in a horizontal direction.

The patterning slit sheet and the deposition unit in each of the chambers may be configured to reciprocate between the plurality of substrates in the vertical direction, and the plurality of substrates may be movable horizontally between adjacent chambers of the plurality of chambers.

The chamber may include a plurality of chambers arranged successively, the substrate may include substrates arranged at opposite sides of the chuck in each of the chambers, and the patterning slit sheet and the deposition unit may be successively arranged at a rear portion of each of the substrates.

The patterning slit sheet and the deposition unit in each of the chambers may be configured to reciprocate between the plurality of substrates in the vertical direction, and the plurality of substrates may be movable horizontally between adjacent chambers of the plurality of chambers.

According to another embodiment of the present invention, a method of manufacturing an organic light emitting display apparatus includes: arranging an organic layer deposition apparatus including a deposition unit for discharging a deposition raw material and a scanning unit including a patterning slit sheet having a plurality of patterning slits to be spaced apart from a carrier including a chuck on which a substrate is mounted for forming an organic layer in a chamber, the patterning slit sheet being smaller than the substrate in at least one of a first direction or a second direction perpendicular to the first direction; and depositing the deposition raw material on the substrate while moving the scanning unit relative to the carrier.

In one embodiment, the substrate includes a plurality of substrates, and the method further includes: arranging the substrates spaced apart from each other in a horizontal direction in the chamber; arranging the patterning slit sheet and the deposition unit at a lower portion of the substrates in a vertical direction; and moving the patterning slit sheet and the deposition unit in parallel with the substrates in connection with each other to deposit the deposition raw material on the substrates.

In one embodiment, the substrate includes a plurality of substrates, and the chamber includes a plurality of chambers, and the method further includes: arranging the substrates spaced apart from each other in a vertical direction in each of the chambers; arranging the patterning slit sheet and the deposition unit at a rear portion of the substrates in a horizontal direction; and moving the patterning slit sheet and the deposition unit in parallel with the substrates in connection with each other to deposit the deposition raw material on the substrates.

The method may further include, after finishing the deposition, moving the substrate to an adjacent chamber in a direction crossing another direction in which the patterning slit sheet and the deposition unit are moved.

The method may further include installing an align stage unit at a lower portion of the patterning slit sheet to align the patterning slit sheet to be parallel with the substrate, the align stage unit including a first location controller coupled to the lower portion of the patterning slit sheet to correct an inclination angle of the patterning slit sheet in X, Y, and Z-axis directions, and a second location controller installed at a lower portion of the first location controller to correct a twisting angle of the patterning slit sheet on the same plane.

### BRIEF DESCRIPTION OF THE DRAWINGS

The above and other features and aspects of the present invention will become more apparent by describing in further detail some exemplary embodiments thereof with reference to the attached drawings in which:

FIG. 1 is a perspective view of an organic layer deposition apparatus according to an embodiment of the present invention;

FIG. 2 is a side cross-sectional view of the organic layer deposition apparatus of FIG. 1;

FIG. 3 is a front cross-sectional view of the organic layer deposition apparatus of FIG. 1;

FIG. 4 is a schematic cross-sectional diagram showing a state in which a scanning unit and an align stage unit of the organic layer deposition apparatus of FIG. 1 move with respect to a carrier unit;

FIG. 5 is a perspective view of an organic layer deposition apparatus according to another embodiment of the present invention;

FIG. 6 is a perspective view of an organic layer deposition apparatus according to another embodiment of the present invention;

FIG. 7 is a perspective view of an organic layer deposition apparatus according to another embodiment of the present invention;

FIG. 8 is a perspective view of an organic layer deposition apparatus according to another embodiment of the present invention; and

FIG. 9 is a cross-sectional view of an active matrix type organic light emitting display apparatus manufactured by using an organic layer deposition apparatus according to an embodiment of the present invention.

### DETAILED DESCRIPTION

Hereinafter, some exemplary embodiments of the present invention are described in further detail with reference to the accompanying drawings; however, embodiments of the present invention may be embodied in different forms and should not be construed as limited to the exemplary embodiments illustrated and set forth herein. Rather, these exemplary embodiments are provided by way of example for understanding of the invention and to convey the scope of the invention to those skilled in the art. As those skilled in the art would realize, the described embodiments may be modified in various ways, all without departing from the spirit or scope of the present invention. As used herein, the term “and/or” includes any and all combinations of one or more of the associated listed items. Expressions such as “at least one of,” when preceding a list of elements, modify the entire list of elements and do not modify the individual elements of the list.

It will be understood that although the terms first and second are used herein to describe various elements, these elements should not be limited by these terms. These terms are only used to distinguish one element from another element. Thus, a first element discussed below could be termed a second element, and similarly, a second element may be termed a first element without departing from the teachings of this disclosure.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Hereinafter, some exemplary embodiments of an organic layer deposition apparatus will be described in further detail with reference to accompanying drawings.

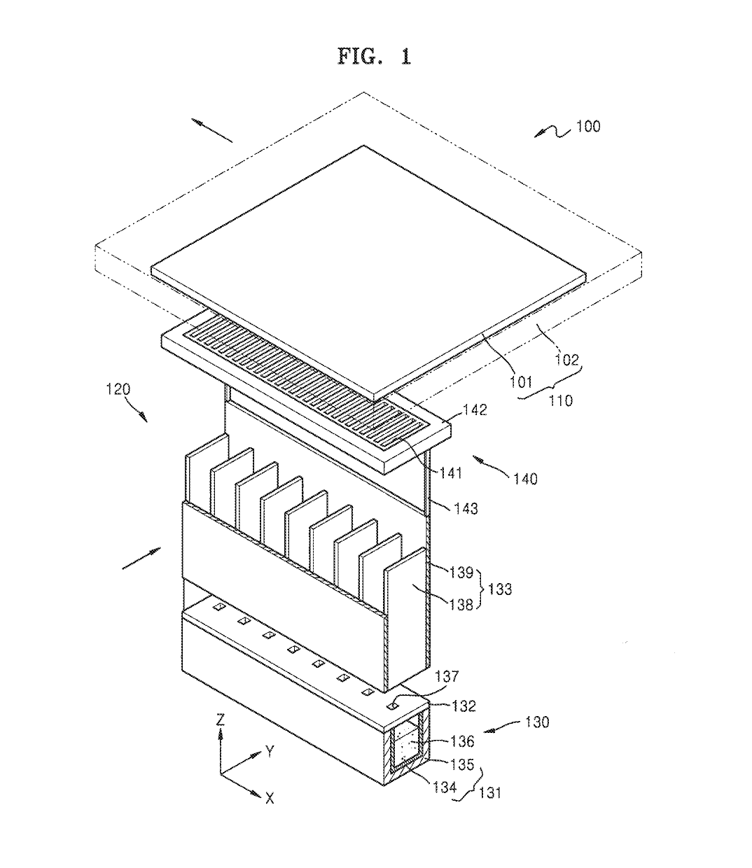

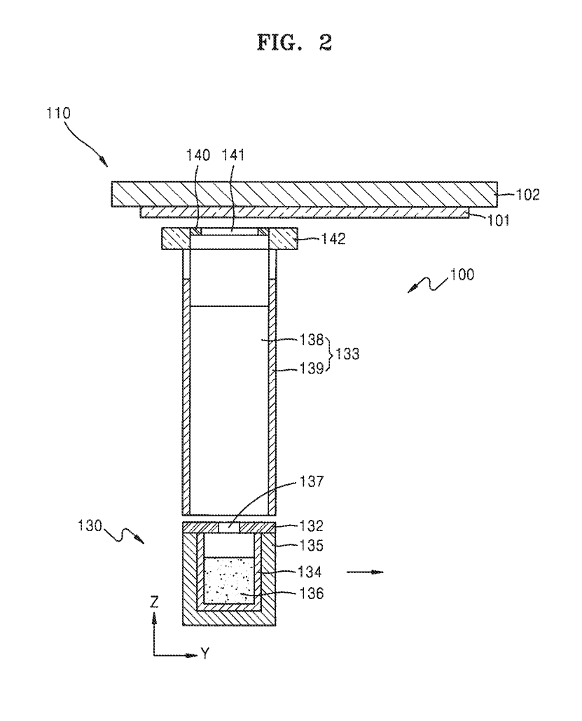

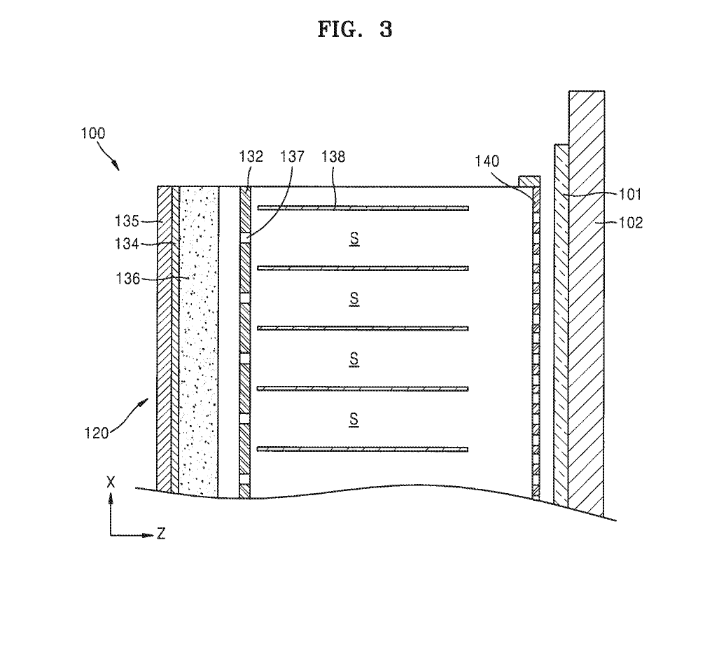

FIG. 1 is a perspective view of an organic layer deposition apparatus 100 according to an embodiment of the present invention; FIG. 2 is a side-sectional view of the organic layer deposition apparatus 100 of FIG. 1; and FIG. 3 is a plan cross-sectional view of the organic layer deposition apparatus 100.

Here, a chamber is not shown in FIGS. 1 through 3 for reasons of clarity; however, all components shown in FIGS. 1 through 3 may be provided under a vacuum (e.g., a predetermined vacuum level), such as in a vacuum chamber, for moving a raw material of an organic layer to be deposited straight.

Referring to FIGS. 1 through 3, the organic layer deposition apparatus 100 includes a carrier 110 and a scanning unit 120.

The carrier 110 includes a chuck 102 on which a substrate 101 for forming an organic layer is mounted.

The substrate 101 may be a large-sized substrate on which a thin film layer such as an organic layer is deposited, such as a substrate applied to an ultra-thin display apparatus of 40 inches or greater, for example.

The chuck 102 is a supporting unit for attaching the substrate 101 during a deposition process. The chuck 102 may be an electrostatic chuck (ESC) including an electrode to which an electric power is applied, and buried in a main body and attaching the substrate on a surface of the main body by using static electricity, or a physical sticking chuck (PSC) supporting the substrate by attaching an ionized film on a surface of a main body thereof. The chuck 102 supports the substrate 101 from a surface of the substrate 101 opposite to a surface of the substrate 101 facing the scanning unit 120 such that a deposition surface of the substrate 101 faces the scanning unit 120.

The scanning unit 120 includes a deposition unit 130 for discharging a deposition raw material 136, and a patterning slit sheet 140 in which a plurality of patterning slits 141 is formed. The deposition unit 130, in one embodiment, includes a deposition source 131, a deposition source nozzle unit 132, and a barrier plate assembly 133.

The deposition source 131, in one embodiment, includes a crucible 134, in which the deposition raw material 136 is filled, and a cooling block 135 surrounding the crucible 134. The cooling block 135 prevents or substantially prevents radiation of heat from the crucible 134 outside, i.e. into the chamber. The cooling block 135 may include a heater (not shown) that heats the crucible 134.

The deposition source nozzle unit 132 is disposed at a side of the deposition source 131, and in particular, at the side of the deposition source 131 facing the substrate 101. The deposition source nozzle unit 132 includes a plurality of deposition source nozzles 137 arranged at intervals (e.g., at equal intervals in an X-axis direction). The deposition raw material 136 that vaporizes in the deposition source 131 passes through the plurality of deposition source nozzles 137 toward the substrate 101.

The barrier plate assembly 133 is disposed between the deposition source nozzle unit 132 and the patterning slit sheet 140. The barrier plate assembly 133 includes a plurality of barrier plates 138 arranged at intervals (e.g., at equal intervals in parallel with each other along the X-axis direction).

Each of the barrier plates 138 may be arranged parallel to a y-z plane, as depicted in FIG. 1, and may have a rectangular shape. The plurality of barrier plates 138 arranged as described above partitions the space between the deposition source nozzles 137 and the patterning slit sheet 140 into a plurality of sub-deposition spaces S. In the organic layer deposition apparatus 100 according to an embodiment of the present invention, a deposition space is divided by the barrier plates 138 into the sub-deposition spaces S that respectively correspond to the deposition source nozzles 137 through which the deposition raw material 136 is discharged.

The barrier plates 138 may be respectively disposed between adjacent deposition source nozzles 137. In other words, each of the deposition source nozzles 137 may be disposed between two adjacent barrier plates 138. In one embodiment, the deposition source nozzles 137 may be respectively located at a midpoint between two adjacent barrier plates 138.

However, the present invention is not limited to this structure. For example, a plurality of deposition source nozzles 137 may be disposed between two adjacent barrier plates 138. In this case, the deposition source nozzles 137 may also be respectively located at a midpoint between two adjacent barrier plates 138.

As described above, since the barrier plates 138 partition the space between the deposition source nozzle unit 132 and the patterning slit sheet 140 into the plurality of sub-deposition spaces S, the deposition raw material 136 discharged through each of the deposition source nozzles 137 is not mixed with the deposition raw material 136 discharged through the other deposition source nozzles 137, and passes through the patterning slits 141 so as to be deposited on the substrate 101.

That is, the barrier plates 138 guide the deposition raw material 136 to move straight or substantially straight, and accordingly, a smaller shadow zone may be formed on the substrate 101. Thus, the scanning unit 120 and, in particular, the patterning slit sheet 140, may be separated by a distance (e.g., a predetermined distance) from the substrate 101.

In one embodiment, a barrier plate frame 139 is disposed at an outside of the barrier plates 138.

The patterning slit sheet 140 in which the plurality of patterning slits 141 are formed is disposed between the substrate 101 and the barrier plate assembly 133. The patterning slits 141 are arranged in a direction (e.g., the x-axis direction) to be separated from each other, and extend in a direction (e.g., the y-axis direction). The deposition raw material 136 that has vaporized in the deposition source 131 and passed through the deposition source nozzles 137 passes through the patterning slits 141 toward the substrate 101. In one embodiment, the patterning slit sheet 140 is fixed to a frame 142 that may be formed as a rectangular or square frame.

The patterning slit sheet 140 may be formed of a metal thin film. The patterning slit sheet 140, in one embodiment, is fixed to the frame 142 such that a tensile force is exerted thereon. The patterning slits 141 may be formed by etching the patterning slit sheet 140 to have a stripe pattern. In one embodiment, the number of patterning slits 141 may correspond to the number of deposition patterns that are to be formed on the substrate 101.

In one embodiment, the barrier plate assembly 133 and the patterning slit sheet 140 may be disposed separate or spaced apart from each other by a distance (e.g., a predetermined distance). In another embodiment, as depicted in FIG. 1, the barrier plate assembly 133 and the patterning slit sheet 140 may be connected by a connection member 143.

According to one embodiment, the carrier 110 may be fixed and the scanning unit 120 moves relative to the carrier 110. For example, the scanning unit 120 is installed to be movable with respect to the carrier 110 along a direction (e.g., the Y-axis direction).

According to a conventional fine metal mask (FMM) deposition method, a mask is equal to or greater in size than the substrate. Therefore, as a size of the substrate increases, the mask has to be larger. Thus, it is not easy to manufacture a large-sized mask, and it is not easy to extend the mask to align the mask in an accurate pattern.

However, in the organic layer deposition apparatus 100 according to the present invention, the deposition is performed while the scanning unit 120 moves relative to the carrier 110 on which the substrate 101 is placed.

In one embodiment, the scanning unit 120 disposed under the substrate 101 in a vertical direction moves along the Y-axis direction to perform the deposition continuously. In other words, the scanning unit 120 moves in the Y-axis direction to perform the deposition in a scanning manner.

Accordingly, the organic layer deposition apparatus 100 may use the patterning slit sheet 140 that is significantly smaller than a mask of a conventional FMM method.

The organic layer deposition apparatus 100 may perform the deposition continuously, that is, in the scanning manner, while the scanning unit 120 moves relative to the substrate 101 continuously in the Y-axis direction. Therefore, a width of the patterning slit sheet 140 in the Y-axis direction may be less than that of the substrate 101, provided that a length of the patterning slit sheet 140 in the X-axis direction is substantially the same as a length of the substrate 101 in the X-axis direction.

In one embodiment, even if the length of the patterning slit sheet 140 in the X-axis direction is less than that of the substrate 101 in the X-axis direction, the deposition may be performed throughout the entire area of the substrate 101 in the scanning manner due to the relative movement of the scanning unit 120 with respect to the substrate 101.

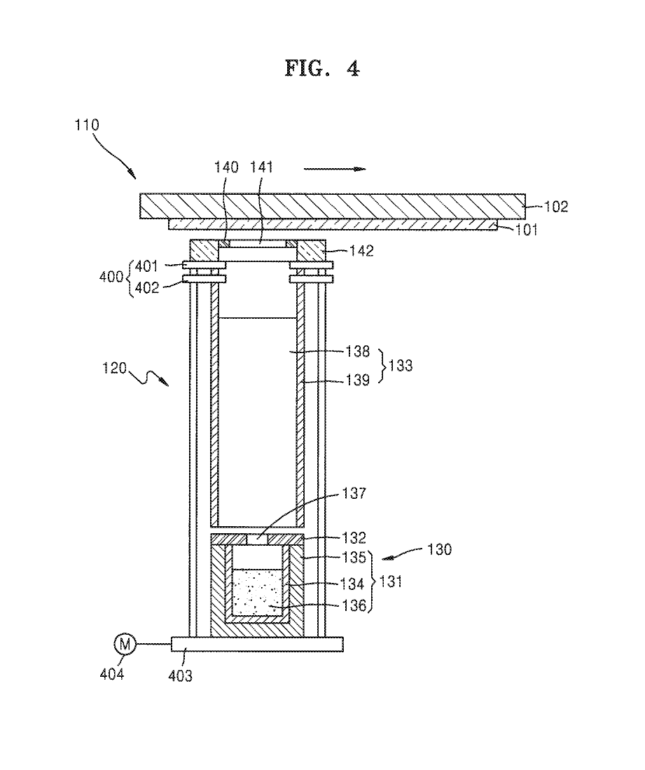

In one embodiment, an align stage unit 400 (see FIG. 4) controls a location of the patterning slit sheet 140 with respect to the substrate 101 to maintain a distance between the substrate 101 and the patterning slit sheet 140.

FIG. 4 is a schematic side cross-sectional view of the organic layer deposition apparatus 100 in which the align stage unit 400 is installed according to an embodiment of the present invention.

Referring to FIG. 4, an organic layer deposition apparatus according to an embodiment of the present invention includes the align stage unit 400 for controlling the location of the patterning slit sheet 140 with respect to the substrate 101. The align stage unit 400 is coupled to the scanning unit 120, and controls the location of the patterning slit sheet 140 such that the patterning slit sheet 140 may be arranged in parallel with the substrate 101 in a state of being separated or spaced apart by a distance (e.g., a predetermined distance) from the substrate 101.

In one embodiment, the align stage unit 400 is a driving stage that is located under the patterning slit sheet 140. When depositing the organic layer, the align stage unit 400 corrects a location error of the patterning slit sheet 140 with respect to the substrate 101 in real time.

The align stage unit 400, in one embodiment, includes a first location controller 401, and a second location controller 402 installed on a lower portion of the first location controller 401.

In one embodiment, the first location controller 401 controls the distance between the substrate 101 and the patterning slit sheet 140 to be constant so as not to cause a shadow problem. For example, an inclination of the patterning slit sheet 140 with respect to the substrate 101, such as an inclination in the X-axis direction (e.g., a roll angle), an inclination in the Y-axis direction (e.g., a pitch angle), or an inclination in the Z-axis direction may be corrected.

The second location controller 402 controls a location error between the substrate 101 and the patterning slit sheet 140. For example, an angle of inclination of the patterning slit sheet 140 with respect to the substrate 101 at the same plane, that is, a twisting angle in the Y-axis direction or an angle of inclination with respect to a center axis (e.g., a yaw angle) may be corrected.

Structures and operations of an align stage unit are well known to those in the art, and thus further detailed descriptions thereof are not provided here.

In one embodiment, when the substrate 101 is moved by using a linear motion (LM) system, the align stage unit 400 may include various devices for rotating a sensor, a camera, an image processing apparatus, or the first and second location controllers 401 and 402 at a desired angle in order to align the location of the patterning slit sheet 140 with respect to the substrate 101.

The align stage unit 400 is moved in connection with the scanning unit 120. In one embodiment, the scanning unit 120 and the align stage unit 400 are integrally coupled to each other on a base frame 403. That is, the deposition unit 130 including the deposition source 131, the deposition source nozzle unit 132, and the barrier plate assembly 133, the patterning slit sheet 140 located on the deposition unit 130 and including the patterning slits 141, and the align stage unit 400 that is located under an edge portion of the patterning slit sheet 140 are coupled to each other on the base frame 403. A driving unit 404 is connected to the base frame 403 in order to move the deposition unit 130, the patterning slit sheet 140, and the align stage unit 400 in connection with each other.

Processes of forming an organic layer of an organic light emitting display apparatus by using the organic layer deposition apparatus 100 having the above structure will be described with reference to FIGS. 1 through 4.

Here, the process of depositing the organic layer is described with respect to a case where an organic layer of a color is deposited in one vacuum chamber; however, the above process may be applied to a case where a plurality of chambers are installed.

The substrate 101 that is supported by the chuck 102 is located in the chamber. In one embodiment, after finishing the deposition of the organic layer of a color on the substrate 101, the substrate 101 may be moved to an adjacent chamber so as to form an organic layer of another color.

The scanning unit 120 that is installed at a lower portion of the substrate 101 supported by the chuck 102 is moved by a distance (e.g., a predetermined distance) along a direction (e.g., the Y-axis direction). When the scanning unit 120 is moved, the deposition raw material 136 filled in the crucible 134 included in the deposition source 131 is vaporized by the heat from the heater. The vaporized deposition raw material 136 passes through the plurality of nozzles 137 included in the deposition source nozzle unit 132 that is installed at an upper portion of the deposition source 131 toward the substrate 101.

The deposition raw material 136 passes through the plurality of sub-deposition spaces S that is divided by the plurality of barrier plates 138 installed between the deposition source nozzle unit 132 and the patterning slit sheet 140 and through the patterning slits 141 included in the patterning slit sheet 140, and then is deposited at a desired position on the substrate 101. The patterning slit sheet 140 is separated or spaced apart by a distance (e.g., a predetermined distance) from the substrate 101.

In one embodiment, the location of the patterning slit sheet 140 with respect to the substrate 101 is monitored and/or controlled by the align stage unit 400 that is installed under the patterning slit sheet 140, and thus the location error or the distance may be measured and corrected in real time during the film formation process.

As described above, the deposition process of the organic layer on the substrate 101 may be performed while the scanning unit 120 moves along a direction (e.g., the Y-axis direction) in the scanning manner.

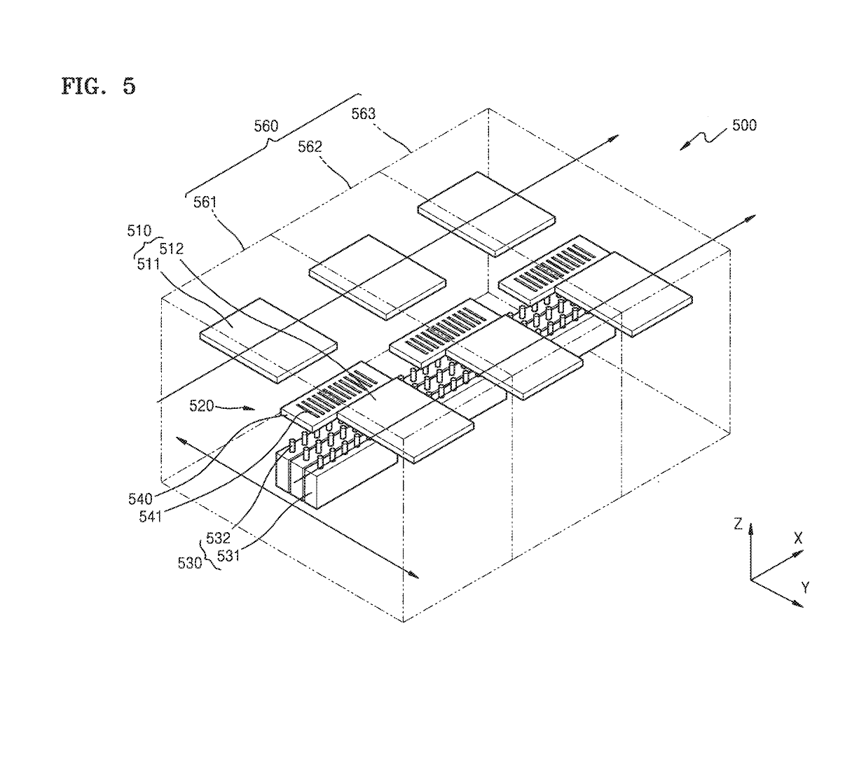

FIG. 5 is a perspective view of an organic layer deposition apparatus 500 according to another embodiment of the present invention.

Hereinafter, in embodiments described below, structures of the substrate, the deposition unit, and the patterning slit sheet are described with respect to the deposition of the organic layer by the relative movements between the above elements, and the other components may be the same or similar as those of the organic layer deposition apparatus 100 described above with respect to FIGS. 1 through 4.

Referring to FIG. 5, the organic layer deposition apparatus 500 includes a plurality of chambers 560. The chambers 560 are arranged successively in a direction (e.g., an X-axis direction). The chambers 560 may include a first chamber 561 for forming a blue organic layer, a second chamber 562 for forming a green organic layer, and a third chamber 563 for forming a red organic layer that are arranged in a direction (e.g., a horizontal direction). The first through third chambers 561 through 563 respectively provide independent spaces for forming the organic layers of the corresponding colors. In one embodiment, the plurality of chambers 560 are maintained at a vacuum state during the deposition process.

In each of the chambers 560, a plurality of substrates 510 are arranged in a direction (e.g., a Y-axis direction) when forming an organic layer of one color. The plurality of substrates 510 includes a first substrate 511 and a second substrate 512 that are arranged at an upper portion in each of the chambers 560 and separated from each other.

In the organic layer deposition apparatus 100, according to one embodiment, one substrate 101, one deposition unit 130, and one patterning slit sheet 140 are shown in FIG. 1. The above structure uses one substrate 101, and thus it may be easy to ensure accuracy due to a short scanning distance; however, productivity degrades.

In the organic layer deposition apparatus 500, since the plurality of substrates 510 including the first and second substrates 511 and 512 are arranged, movement and deposition preparation of the second substrate 512 are completed during the film formation on the first substrate 511, and thus productivity may be improved.

In one embodiment, in order to improve the productivity further, a plurality of deposition sources and a plurality of patterning slit sheets may be provided in addition to the plurality of substrates.

A scanning unit 520 is disposed under the substrates 510. The scanning unit 520 includes a deposition unit 530 including a deposition source 531 and a deposition source nozzle unit 532, and a patterning slit sheet 540 in which a plurality of patterning slits 541 is formed.

According to an exemplary embodiment, in performing the manufacturing processes, a direction (e.g., a Y-axis direction) in which the scanning unit 520 moves in each of the chambers 560 crosses a direction (e.g., an X-axis direction) in which the substrates 510 in each of the chambers 560 move to another chamber after finishing the formation of the organic layer of the desired color.

In the organic layer deposition apparatus 500 having the above structure, in one embodiment, the scanning unit 520 moves along a direction (e.g., the Y-axis direction) to form the blue organic layer, for example, on a facing surface of the first substrate 511. During performing the film formation on the first substrate 511, the second substrate 512 is carried in the first chamber 561 to perform the film formation process.

After the film formation process on the first substrate 511, the scanning unit 520 is moved to the second substrate 512 to form the blue organic layer, for example, on a facing surface of the second substrate 512.

In one embodiment, the first and second substrates 511 and 512 on which the film formation operations are completed are sequentially stepped along a direction (e.g., the X-axis direction) to be carried in the second and third chambers 562 and 563. In addition, whenever the first and second substrates 511 and 512 are carried in each of the second and third chambers 562 and 563, the organic layer of a desired color, such as the green or red organic layer, for example, is formed on the facing surfaces of the first and second substrates 511 and 512.

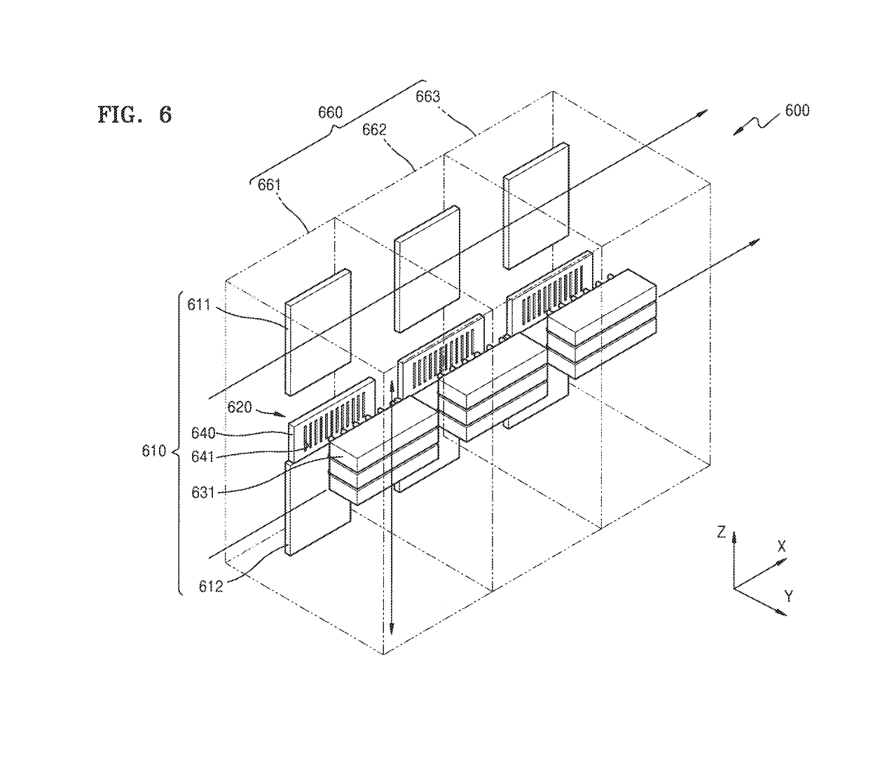

FIG. 6 is a perspective view of an organic layer deposition apparatus 600 according to another embodiment of the present invention.

Referring to FIG. 6, the organic layer deposition apparatus 600 includes a plurality of chambers 660. The chambers 660 are arranged successively in a direction (e.g., an X-axis direction), and may include a first chamber 661 for forming a blue organic layer, a second chamber 662 for forming a green organic layer, and a third chamber 663 for forming a red organic layer.

In each of the chambers 660, a plurality of substrates 610 are arranged in a vertical direction (e.g., a Z-axis direction) when the organic layer of one color is formed. The plurality of substrates 610 includes a first substrate 611 and a second substrate 612 that are arranged on a side in each of the chambers 660 along the Z-axis direction at an interval (e.g., a predetermined interval).

One scanning unit 620 is disposed in a direction (e.g., the Y-axis direction) with respect to the plurality of substrates 610 in each of the chambers 660. The scanning unit 620 includes a deposition source 631, and a patterning slit sheet 640 in which a plurality of patterning slits 641 is formed.

In the organic layer deposition apparatus 500 described above with respect to FIG. 5, the plurality of substrates 510 are arranged in the Y-axis direction to be moved to an adjacent one of the chambers 560 in a step-in-line manner. However, in the organic layer deposition apparatus 600, the plurality of substrates 610 are arranged in the Z-axis direction, and then may be moved to an adjacent one of the chambers 660 in a step-in-line manner after the deposition process.

Since, in one embodiment, the patterning slit sheet 640 is formed of a thin film type material, if the patterning slit sheet 640 were disposed in the horizontal direction, a part of the patterning slit sheet 640, such as a center portion in a lengthwise direction thereof, may be sagged downward and the patterning slits 641 may be deformed and the organic layer may not be formed on a desired portion on the substrates 610. Thus, in the organic layer deposition apparatus 600 according to one embodiment, the substrates 610 and the patterning slit sheet 640 are arranged vertically in the Z-axis direction.

In one embodiment, since the substrates 610 are large, center portions in the lengthwise direction of the substrates 610 may sag downward if the substrates 610 were arranged in the horizontal direction. To avoid this, in one embodiment, the substrates 610 are arranged such that relatively shorter sides may be located in the vertical direction and relatively longer sides may be located in the horizontal direction.

In one embodiment, a direction (e.g., a Z-axis direction) in which the scanning unit 620 moves in each of the chambers 660 may cross a direction (e.g., an X-axis direction) in which the substrate 610 moves to an adjacent one of the chambers 660 in the step-in-line manner after the film formation of the organic layer of the desired color in each of the chambers 660.

In the organic layer deposition apparatus 600 having the above structure, when the scanning unit 620 moves along the Z-axis direction, a blue organic layer, for example, is formed on a facing surface of the first substrate 611 in the first chamber 661. During performing the film formation process on the first substrate 611, the second substrate 612 is carried in the first chamber 661 such that the film formation on the second substrate 612 may be performed.

Next, when the film formation on the first substrate 611 is completed, the scanning unit 620 is moved, such as descended, in the Z-axis direction to form the blue organic layer, for example, on the facing surface of the second substrate 612. The first substrate 611 on which the organic layer is formed is moved in the step-in-line manner along the X-axis direction and is arranged such that an organic layer of another color may be performed.

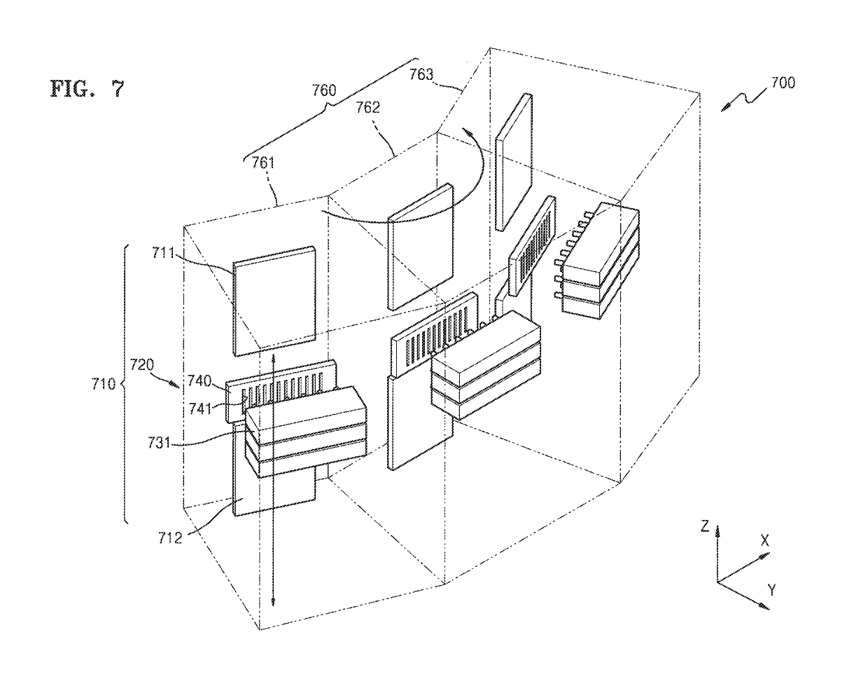

FIG. 7 is a perspective view of an organic layer deposition apparatus 700 according to another embodiment of the present invention.

Referring to FIG. 7, the organic layer deposition apparatus 700 includes a plurality of chambers 760. The plurality of chambers 760 may include a first chamber 761 for forming a blue organic layer, a second chamber 762 for forming a green organic layer, and a third chamber 763 for forming a red organic layer.

In each of the chambers 760, a plurality of substrates 710 are arranged along a vertical direction (e.g., a Z-axis direction) when the organic layer of a color is formed. The plurality of substrates 710 includes a first substrate 711 and a second substrate 712 that are arranged at a side in each of the chambers 760 in the vertical direction at an interval (e.g., a predetermined interval).

A scanning unit 720 is disposed at a rear portion of the substrates 710 in a direction (e.g., an X-axis direction). The scanning unit 720 includes a deposition source 731, and a patterning slit sheet 740 in which a plurality of patterning slits 741 is formed.

Unlike the chambers 560 of the organic layer deposition apparatus 500 and the chambers 660 of the organic layer deposition apparatus 600 described above, the first through third chambers 761 through 763 of the organic layer deposition apparatus 700 according to one embodiment are arranged in a circulation form. The carrier including the chuck (e.g., the chuck 102 of FIG. 1) that moves the substrates 710 is a device requiring high precision, and if the carrier on which the substrate is mounted returns to an original location through a linear reciprocating movement after depositing the blue, green, and red organic layers in the chambers 760 as shown in FIGS. 5 and 6, the precision degree is lowered due to frequent movements of the carrier.

In one embodiment, when the first through third chambers 761 through 763 are arranged in the circulation form, the returning operation of the carrier through the linear reciprocating movement may be omitted in the processes of forming the blue, green, and red organic layers in the chambers while moving the carrier 102 through the chambers. Therefore, the high precision of the carrier may be maintained.

In the organic layer deposition apparatus 700 having the above structure, when the scanning unit 720 moves in the Z-axis direction, the blue organic layer, for example, is formed on the facing surface of the first substrate 711. During performing the film forming process on the first substrate 711, the second substrate 712 is carried in the first chamber 761 such that the film forming process may be performed thereon.

Next, when the film formation on the first substrate 711 is finished, the scanning unit 720 is moved (e.g., descended) along the Z-axis direction to form the blue organic layer, for example, on the facing surface of the second substrate 712. The first substrate 711 on which the organic layer is formed is moved to another one of the chambers 760 by the circulation, and arranged in another chamber such that the organic layer of another color may be formed thereon.

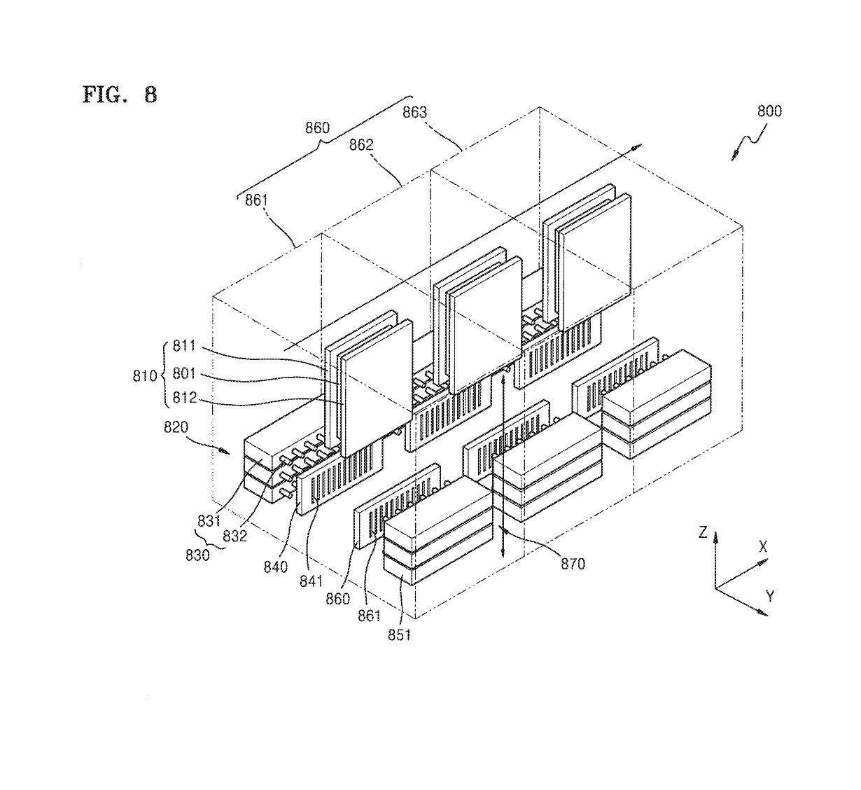

FIG. 8 is a perspective view of an organic layer deposition apparatus 800 according to another embodiment of the present invention.

Referring to FIG. 8, the organic layer deposition apparatus 800 includes a plurality of chambers 860. The plurality of chambers 860 may be arranged successively in a direction (e.g., an X-axis direction), and may include a first chamber 861 for forming a blue organic layer, a second chamber 862 for forming a green organic layer, and a third chamber 863 for forming a red organic layer.

In each of the chambers 860, a plurality of substrates 810 are arranged in a vertical direction (e.g., a Z-axis direction) when forming an organic layer of a color. The plurality of substrates 810 includes a first substrate 811 and a second substrate 812. Here, a carrier including a chuck 801 that moves and supports the first and second substrates 811 and 812 is disposed between the first and second substrates 811 and 812. That is, the first and second substrates 811 and 812 are disposed respectively on opposite sides of the chuck 801 along a direction (e.g., a Y-axis direction).

A first scanning unit 820 is disposed at a rear portion of the first substrate 811 (e.g., in the Y-axis direction). The first scanning unit 820 includes a first deposition unit 830 including a first deposition source 831 and a first deposition source nozzle unit 832, and a first patterning slit sheet 840 in which a plurality of first patterning slits 841 is formed.

A second scanning unit 870 is disposed at a rear portion of the second substrate 812 (e.g., in the Y-axis direction). The second scanning unit 870 includes a second deposition source 851, and a patterning slit sheet 860 in which a plurality of patterning slits 861 is formed.

As described above, the first and second substrates 811 and 812 are disposed at opposite sides of the chuck 801 and the first and second scanning units 820 and 870 are disposed for respectively performing the deposition processes on the first and second substrates 811 and 812, and thus the film formation may be performed concurrently (e.g., simultaneously) on the plurality of substrates 810 by using one carrier system and a scanning stroke may be reduced.

In one embodiment, the chambers 860 are arranged in-line to be adjacent to each other in the horizontal direction (e.g., the X-axis direction); however, in another embodiment, the chambers 860 may be arranged in a circulation form as depicted in FIG. 7. In one embodiment, the above-described structures may be installed in the vertical direction to perform the film formation concurrently (e.g., simultaneously) on four substrates.

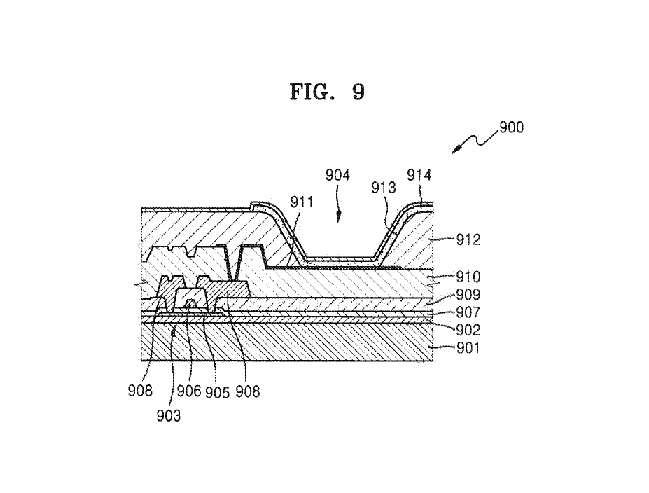

FIG. 9 is a cross-sectional view of an active matrix organic light emitting display apparatus 900 manufactured by using an organic layer deposition apparatus according to an embodiment of the present invention.

Referring to FIG. 9, the active matrix organic light emitting display apparatus 900 according to an embodiment of the present invention is formed on a substrate 901. The substrate 901 may be formed of a transparent material, such as glass, plastic, or metal. An insulating layer 902, such as a buffer layer, is formed on a surface (e.g., an entire surface) of the substrate 901.

A thin film transistor (TFT) 903 and an organic light-emitting diode (OLED) 904 are disposed on the insulating layer 902. A semiconductor active layer 905 is formed on an upper surface of the insulating layer 902 in a pattern (e.g., a predetermined pattern). A gate insulating layer 907 is formed to cover the semiconductor active layer 905. The semiconductor active layer 905 may include a p-type or n-type semiconductor material.

A gate electrode 906 is formed in a region of the gate insulating layer 907 corresponding to the semiconductor active layer 905. An interlayer insulating layer 909 is formed to cover the gate electrode 906. The interlayer insulating layer 909 and the gate insulating layer 906 are etched (e.g., by dry etching) to form a contact hole exposing parts of the semiconductor active layer 905.

A source/drain electrode 908 is formed on the interlayer insulating layer 909 to contact the semiconductor active layer 905 through the contact hole. A passivation layer 910 is formed to cover the source/drain electrode 908, and is etched to expose a part of the drain electrode 908. An insulating layer (not shown) may be further formed on the passivation layer 910 so as to planarize the passivation layer 910.

The OLED 904 displays image information (e.g., predetermined image information) by emitting red, green, or blue light as current flows. The OLED 904 includes a first electrode 911 disposed on the passivation layer 910. The first electrode 911 is electrically connected to the drain electrode 908 of the TFT 903.

A pixel defining layer 912 is formed to cover the first electrode 911. An opening is formed in the pixel defining layer 912, and then an organic layer 913, including an emission layer, is formed in a region defined by the opening. A second electrode 914 is formed on the organic layer 913.

The pixel defining layer 912, which defines individual pixels, is formed of an organic material. The pixel defining layer 912 also planarizes the surface of a region of the substrate 901 where the first electrode 911 is formed, and in particular, the surface of the passivation layer 910. The first electrode 911 and the second electrode 914 are insulated from each other, and respectively apply voltages of opposite polarities to the organic layer 913, including the emission layer, to induce light emission.

The organic layer 913 including the emission layer may be formed of a low-molecular weight organic material or a high-molecular weight organic material. When a low-molecular weight organic material is used, the organic emission layer 913 may have a single or multi-layer structure including at least one selected from the group consisting of a hole injection layer (HIL), a hole transport layer (HTL), an emission layer (EML), an electron transport layer (ETL), and an electron injection layer (EIL). Examples of available organic materials may include copper phthalocyanine (CuPc), N,N′-di(naphthalene-1-yl)-N,N′-diphenyl-benzidine (NPB), tris-8-hydroxyquinoline aluminum (Alq3), and the like.

The first electrode 911 may function as an anode, and the second electrode 914 may function as a cathode. Alternatively, the first electrode 911 may function as a cathode, and the second electrode 914 may function as an anode. The first electrode 911 may be patterned to correspond to individual pixel regions, and the second electrode 914 may be formed to cover all the pixels.

The first electrode 911 may be formed as a transparent electrode or a reflective electrode. Such a transparent electrode may be formed of indium tin oxide (ITO), indium zinc oxide (IZO), zinc oxide (ZnO), or indium oxide (In₂O₃). Such a reflective electrode may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer of ITO, IZO, ZnO, or In₂O₃ on the reflective layer. The first electrode 911 may be formed by forming a layer by, for example, sputtering, and then patterning the layer by, for example, photolithography.

The second electrode 914 may also be formed as a transparent electrode or a reflective electrode. When the second electrode 914 is formed as a transparent electrode, the second electrode 914 functions as a cathode. To this end, such a transparent electrode may be formed by depositing a metal having a low work function, such as lithium (Li), calcium (Ca), lithium fluoride/calcium (LiF/Ca), lithium fluoride/aluminum (LiF/Al), aluminum (Al), silver (Ag), magnesium (Mg), or a compound thereof and forming an auxiliary electrode layer or a bus electrode line thereon from ITO, IZO, ZnO, In₂O₃, or the like. When the second electrode 914 is formed as a reflective electrode, the reflective layer may be formed by depositing Li, Ca, LiF/Ca, LiF/Al, Al, Ag, Mg, or a compound thereof on the entire surface of the organic layer 913. The second electrode 914 may be formed by using the same deposition method as used to form the organic layer 913 including the emission layer described above.

The organic layer deposition apparatus according to the embodiments of the present invention described above may be applied to form an organic layer or an inorganic layer of an organic TFT, and to form layers from various materials.

As described above, in an organic layer deposition apparatus according to the present invention and a method of manufacturing an organic light emitting display apparatus by using the organic layer deposition apparatus, the organic layer deposition apparatus may be easily manufactured, and may be simply applied to the manufacture of large-sized display devices on a mass scale. In addition, the deposition system may be simplified, the deposition time may be reduced, and contamination of the chambers may be prevented or substantially prevented.

While the present invention has been particularly shown and described with reference to some exemplary embodiments thereof, it will be understood by those of ordinary skill in the art that various changes in form and details may be made without departing from the spirit and scope of the present invention as defined by the following claims, and equivalents thereof.

What is claimed is:

1. An organic layer deposition apparatus comprising:
a carrier including a chuck on which a substrate is mounted to form an organic layer;
a scanning unit comprising a deposition unit for discharging a deposition raw material, and a patterning slit sheet having a plurality of patterning slits, the patterning slit sheet being smaller than the substrate in at least one of a first direction or a second direction perpendicular to the first direction; and
a chamber accommodating the carrier and the scanning unit,
wherein the scanning unit is arranged to be spaced apart from the substrate and movable relative to the carrier.

2. The organic layer deposition apparatus of claim 1, wherein the deposition unit comprises:
a deposition source arranged at a side of the carrier to discharge the deposition raw material;
a deposition source nozzle unit on the deposition source and comprising a plurality of nozzles; and
a barrier plate assembly between the patterning slit sheet and the deposition source nozzle unit, and comprising a plurality of barrier plates partitioning a space between the patterning slit sheet and the deposition source nozzle unit into a plurality of sub-deposition spaces.

3. The organic layer deposition apparatus of claim 1, wherein the patterning slit sheet is spaced apart from the substrate.

4. The organic layer deposition apparatus of claim 1, wherein the chuck is installed on a surface of the substrate, which is opposite to a surface of the substrate facing the scanning unit, for supporting the substrate.

5. The organic layer deposition apparatus of claim 1, wherein the substrate comprises a plurality of substrates arranged in the chamber, and the scanning unit is configured to reciprocate between the plurality of substrates.

6. The organic layer deposition apparatus of claim 1, further comprising an align stage unit arranged at a lower portion of the patterning slit sheet and comprising at least a location controller for aligning the patterning slit sheet to be parallel with the substrate.

7. The organic layer deposition apparatus of claim 6, wherein the scanning unit and the align stage unit are integrally coupled to each other on a base frame for moving in connection with each other.

8. The organic layer deposition apparatus of claim 1, wherein the chamber comprises a plurality of chambers successively arranged, and the scanning unit is configured to move in a direction in each of the chambers crossing a direction in which the carrier moves between adjacent chambers of the plurality of chambers in a step-in-line manner.

9. The organic layer deposition apparatus of claim 1, wherein the chamber comprises a plurality of chambers successively arranged, the substrate comprises a plurality of substrates spaced apart from each other in a horizontal direction in each of the chambers, and the patterning slit sheet and the deposition unit are successively arranged at a lower portion of the substrates in a vertical direction.

10. The organic layer deposition apparatus of claim 9, wherein the patterning slit sheet and the deposition unit in each of the chambers are configured to reciprocate between the plurality of the substrates horizontally in a direction, and the plurality of substrates are movable between adjacent chambers of the plurality of chambers in a step-in-line manner in another direction crossing the direction.

11. The organic layer deposition apparatus of claim 1, wherein the chamber comprises a plurality of chambers successively arranged, the substrate comprises a plurality of substrates spaced apart from each other in a vertical direction in each of the chambers, and the patterning slit sheet and the deposition unit are successively arranged at a rear portion of the substrates in a horizontal direction.

12. The organic layer deposition apparatus of claim 11, wherein the patterning slit sheet and the deposition unit in each of the chambers are configured to reciprocate between the plurality of substrates in the vertical direction, and the plurality of substrates are movable horizontally between adjacent chambers of the plurality of chambers.

13. The organic layer deposition apparatus of claim 1, wherein the chamber comprises a plurality of chambers arranged in a circulation form, the substrate comprises a plurality of substrates spaced apart from each other in a vertical direction in each of the chambers, and the patterning slit sheet and the deposition unit are successively arranged at a rear portion of the substrates in a horizontal direction.

14. The organic layer deposition apparatus of claim 13, wherein the patterning slit sheet and the deposition unit in each of the chambers are configured to reciprocate between the plurality of substrates in the vertical direction, and the plurality of substrates are movable horizontally between adjacent chambers of the plurality of chambers.

15. The organic layer deposition apparatus of claim 1, wherein the chamber comprises a plurality of chambers arranged successively, the substrate comprises substrates arranged at opposite sides of the chuck in each of the chambers, and the patterning slit sheet and the deposition unit are successively arranged at a rear portion of each of the substrates.

16. The organic layer deposition apparatus of claim 15, wherein the patterning slit sheet and the deposition unit in each of the chambers are configured to reciprocate between the plurality of substrates in the vertical direction, and the plurality of substrates are movable horizontally between adjacent chambers of the plurality of chambers.

17. A method of manufacturing an organic light emitting display apparatus, the method comprising:
arranging an organic layer deposition apparatus including a deposition unit for discharging a deposition raw material and a scanning unit including a patterning slit sheet having a plurality of patterning slits to be spaced apart from a carrier including a chuck on which a substrate is mounted for forming an organic layer in a chamber, the patterning slit sheet being smaller than the substrate in at least one of a first direction or a second direction perpendicular to the first direction; and
depositing the deposition raw material on the substrate while moving the scanning unit relative to the carrier.

18. The method of claim 17, wherein the substrate comprises a plurality of substrates, the method further comprising:
arranging the substrates spaced apart from each other in a horizontal direction in the chamber;
arranging the patterning slit sheet and the deposition unit at a lower portion of the substrates in a vertical direction; and
moving the patterning slit sheet and the deposition unit in parallel with the substrates in connection with each other to deposit the deposition raw material on the substrates.

19. The method of claim 17, wherein the substrate comprises a plurality of substrates, and the chamber comprises a plurality of chambers, the method further comprising:
arranging the substrates spaced apart from each other in a vertical direction in each of the chambers;
arranging the patterning slit sheet and the deposition unit at a rear portion of the substrates in a horizontal direction; and
moving the patterning slit sheet and the deposition unit in parallel with the substrates in connection with each other to deposit the deposition raw material on the substrates.

20. The method of claim 17, further comprising, after finishing the deposition, moving the substrate to an adjacent chamber in a direction crossing another direction in which the patterning slit sheet and the deposition unit are moved.

21. The method of claim 17, further comprising installing an align stage unit at a lower portion of the patterning slit sheet to align the patterning slit sheet to be parallel with the substrate, the align stage unit comprising a first location controller coupled to the lower portion of the patterning slit sheet to correct an inclination angle of the patterning slit sheet in X, Y, and Z-axis directions, and a second location controller installed at a lower portion of the first location controller to correct a twisting angle of the patterning slit sheet on the same plane.
